(19) United States
(12) Patent Application Publication
(10) Pub. No.: US 2020/0257831 A1
(43) Pub. Date: Aug. 13, 2020

(54) LED LIGHTING SIMULATION SYSTEM

(71) Applicant: Eaton Intelligent Power Limited, Dublin (IE)

(72) Inventors: Paul A. Boudreau, Lawrenceville, GA (US); Parth Joshi, Atlanta, GA (US); Debora Yoon Grosse, Atlanta, GA (US); Nam Chin Cho, Peachtree City, GA (US)

(21) Appl. No.: 16/787,292

(22) Filed: Feb. 11, 2020

Related U.S. Application Data
(60) Provisional application No. 62/804,808, filed on Feb. 13, 2019.

(51) Int. Cl. G06F 30/13; G06T 19/00; G06F 30/20; G06T 15/50; G06T 11/00; G06T 17/00; H05B 47/11

(52) U.S. Cl. CPC G06F 30/13; G06T 19/006; G06F 30/20; G06T 2210/04; G06T 11/00; G06T 17/00; H05B 47/11; G06T 15/506

(57) ABSTRACT

A lighting device simulation system simulates operation of luminaires in a facility according to scene by using location and capability data for the luminaires and mapping it to structural feature data for the facility. In response to receiving a selection of a scene, the system will play the selected scene on a display. The display may be a two-dimensional representation of the facility, or it may be a three-dimensional representation on an augmented reality or mixed reality device.

RELATED APPLICATIONS AND CLAIM OF PRIORITY

This patent document claims priority to United States Provisional Patent Application Number 62/804,808, filed Feb. 13, 2019. The disclosure of the priority application is fully incorporated into this document by reference.

### BACKGROUND

Many entertainment, commercial, and industrial facilities use light emitting diode (LED) based luminaires for lighting. The LED based luminaires provide these facilities with the ability to achieve smart control of high quality light, reliable light output, adjustable shape and intensity of the light, and improved energy efficiency. In addition, lighting systems that include light emitting diode (LED) luminaires or other types of luminaires may offer features such as controllable dimming, color selection and color tuning, color temperature adjustment Dᵤᵥ control, or control of the shape and/or direction of emitted light beams.

In facilities such as sports arenas, stadiums, theaters, and other entertainment venues may have large numbers of LED luminaires. Facility operators may want to make frequent changes to the characteristics of light output by the devices. Thus, they must program their lighting control systems with parameters that will be used to command the lighting devices to emit light of varying characteristics. In systems with large numbers of lights, this programming can be very time-consuming, and it can be very difficult to verify the results of the programming or assess potential changes to the parameters used. Currently, operators must program the facility and observe the lights in place, which requires a significant amount of time and energy, especially when testing large numbers of potential changes. This can take away the time that the lighting systems are available for operation to illuminate an event, and it can make programming errors extremely difficult to troubleshoot and fix.

This document describes a system that is directed to solving the issues described above, and/or other issues.

### SUMMARY

In various embodiments, a lighting device simulation system includes a data store containing location data for luminaires that are located in a facility, along with one or more characteristics of light that each of the luminaires is capable of emitting. The system also includes a data store containing structural feature data for the facility, along with location data for the structural features. The system also includes a data store containing scene data for scenes that may be used to control operation of the luminaires. The system also includes a processor, a display, and programming instructions that are configured to cause the processor to, in response to receiving a selection of one of the scenes, play the selected scene. The processor plays the scene by mapping location data for structural features of the facility to points on the display, mapping location data for a group of the luminaires of the facility to a subset of the points on the display, and causing the display to output virtual representations of luminaires in the group at each point in the subset of points. While outputting each virtual representation, for each of a plurality of time elements in the scene, the system will identify one or more light output characteristics for the luminaire, and it will cause the virtual representation to output a visual indicator that corresponds to the light output characteristics so that the visual indicators for at least some of the virtual representations are varied over time.

In two-dimensional embodiments, the system may cause the display to display the structural features of the facility at the points on the display, and when causing the display to output the virtual representations, the system may superimpose the virtual representations over a portion of the structural features as presented on the display. In three-dimensional embodiments, the display may include an augmented reality display or mixed reality display, and the system may superimpose the virtual representations over a portion of the structural features of the actual facility as seen on the display.

In some embodiments, the system includes a camera, and when the display outputs the virtual representations of the luminaires the system may superimpose the virtual representations over a portion of the structural features of the actual facility as seen in images captured by the camera and presented on the display.

In some embodiments, when the simulator identifies one or more light output characteristics for the luminaire and causes the virtual representation to output a visual indicator that corresponds to the light output characteristics, the system may receive the scene data as a stream of data packets, wherein the data packets comprise a plurality of channels of data., Upon receipt of each channel of data, the system may identify a luminaire in the facility that subscribes to that channel, extract the one or more light output characteristics from that channel, and use the extracted light output characteristics to apply color and brightness values to one or pixels or voxels of the display that are associated with the virtual representation of the identified luminaire.

In some embodiments, when outputting a visual indicator that corresponds to the light output characteristics for each luminaire, the system may determine a color value for the luminaire and a beam spread for emitted light that is associated with the luminaire. The system may then perform either or both of the following when the luminaire is on in the selected scene: (a) apply a darkening filter to pixels that are not within the beam spread of the emitted light associated with the luminaire; or (b) apply a light filter to pixels that are within the beam spread of the emitted light associated with the luminaire.

In some embodiment, when the system receives, via the user interface, a modification to one or more light output characteristics for the luminaire, it may save the modification to a memory as a modified scene, and it may also present the modification on the display by playing the modified scene.

In some embodiments, when the system detect a user input has selected a luminaire that is being output on the screen, then in response to the user input the system may present on the display a pop-up box that shows characteristics of the selected luminaire or settings of the luminaire. To present the pop-up box, the system may extract, from the scene data for the selected scene, characteristics of light that the selected luminaire is emitting in the scene at the time that the user input is received. The system may then include in the box information about the characteristics of light that the selected luminaire is emitting in the scene at the time that the user input is received.

In some embodiments, when playing the selected scene, the system may retrieve display models for each of the luminaires in the group. The system may combine some or all of the display models to generate an overall display model representing a combined lighting pattern for some or all the luminaires in the group. Then, when causing the display to output virtual representations of the luminaires in the group, The system also may cause the display to output a visual representation of the combined lighting pattern in the facility. Optionally, the system also may receive, from an ambient light sensor, an actual lighting condition for the facility at a location in the facility. If the system receives this information from an ambient light sensor, then when generating the overall display model representing the combined lighting pattern the system may also factor characteristics of the actual lighting condition into the combined lighting pattern. In some embodiments, when playing the selected scene, the system also may display illuminance values of one or more pixels or voxels at corresponding locations within the visual representation of the combined lighting pattern.

### BRIEF DESCRIPTION OF THE DRAWINGS

FIG. 1 illustrates an example of a network of lighting devices, with a proximate mobile electronic device and remote server that are used to control the light emitted by the network of devices.

FIG. 2 illustrates an example display that may be used in a lighting simulation system.

FIGS. 3A and 3B illustrate how the example display may play a scene.

FIG. 4 illustrates an example feature of the display of FIG. 2.

FIG. 5 illustrates example three-dimensional display devices that may be used in a lighting simulation system.

FIG. 6 illustrates an example 3D model of a luminaire and its resulting lighting pattern.

FIG. 7 illustrates an additional example 3D model of a luminaire and its resulting lighting pattern.

FIGS. 8A illustrates a 2D array that is populated with photometric data, while FIG. 8B illustrates a 2D array that is derived in part from the array of FIG. 8A.

FIG. 9 illustrates various parameters that may be used to calculate the intensity of emitted light at a point on a plane.

FIG. 10A illustrates 3D augmented reality display information mapped from the light illuminance data of the 2D array of FIG. 8B. FIG. 10B illustrates the information of FIG. 10 with light shape.

FIG. 11 illustrates an example of a type of lighting device for which the system may provide a simulation.

FIG. 12 illustrates various hardware components that may be included in one or more electronic devices.

### DETAILED DESCRIPTION

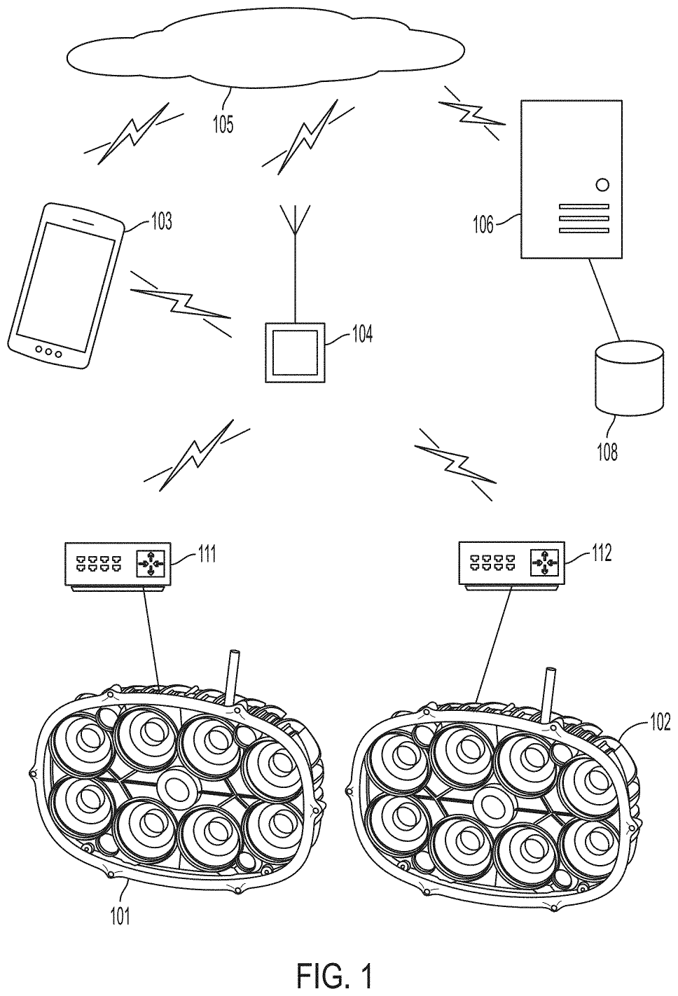

FIG. 1 illustrates a lighting device control system in which any number of lighting devices 101, 102 are positioned at various locations in an environment, such as a wall, ceiling, mast, tower or other supporting structure in a stadium, arena, concert hall, outdoor amphitheater, park or other sports or entertainment facility, or a commercial building or other light-enabled facility. Optionally, a group of lighting devices at the facility may be controlled by a gateway controller 104 communicatively coupled to one or more fixture controllers 111, 112 that are connected to one or more lighting devices 101, 102. If a gateway controller 104 is used, it may be configured to pair with a portable electronic device 103, receive a light operation request from the portable electronic device 103 and control at least one lighting device 101, 102 via the fixture controller 111, 112 according to the light operation request. Alternatively or in addition, the portable electronic device may send control commands directly to a lighting device's fixture controller 111, 112. Each of the fixture controllers 111, 112 includes various components of an illumination device's control circuitry. The portable electronic device 103 may be, for example, a wearable virtual reality, mixed reality or augmented reality device. In other embodiments the portable electronic device 103 may be a laptop, smartphone, tablet or other electronic device.

Each fixture controller, the gateway controller 104 and/or the portable electronic device 103 may be capable of communicating with a communication network 105, such as a cellular communication work, an Internet, a mesh network or other wired or wireless communication networks. A remote server 106 also may be communicatively connected to the communication network 105 so that it can communicate with the portable electronic device, gateway controller 104, and/or fixture controllers 111, 112. The remote server 106 may include or be connected one or more memory devices that collectively store a database 108 of data for the light-enabled facility, such as available scenes (which will be described below). The portable electronic device 103 may include a memory device containing programming instructions that are configured to cause the portable electronic device to perform various functions. In addition or alternatively, the portable electronic device 103 may access the remote server 106 via a communication network 105 to obtain program instructions that are stored on and/or executed by the server.

Often, when multiple luminaires are installed in a stadium or other facility, the system controller (such as the gateway controller, remote server, or electronic device described above) has access to various “scenes,” which are collections of digital files that contain settings data for the luminaires that will control characteristics the light output by each luminaire. When the control equipment plays a scene, it will cause the lighting devices to operate according to the parameters. A scene may include a timeline in which the parameters applied to various lighting devices change over time.

For example, a scene may include settings indicating that a first group of lights will emit light of a first specified characteristic set (e.g., color, shape, beam spread, color temperature and/or brightness) for a first time period. The scene may specify that after the first time period ends, the first group of lights will be turned off, and a second group of lights will be turned on to emit light of a second specified characteristic set for a second time period. In a third time period, the scene may specify that both groups of lights will be operated according to a third specified characteristic set. Any combination of light settings and time periods may be included in the scene.

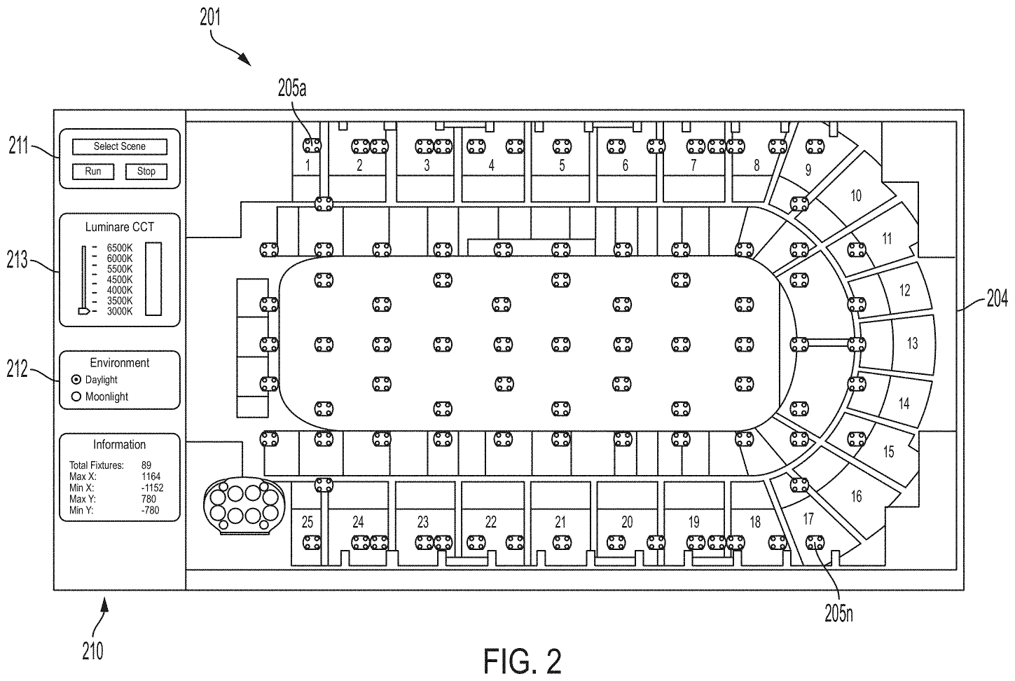

A simulator is an electronic device or system of electronic devices with access to programming instructions, a database of scenes, and data set of geographic data for a facility, and one or data sets with lighting device locations in the facility and optionally capabilities of those devices. The programming instructions will be capable of causing the simulator to display the lighting devices in their locations in the facility, characteristics of light output by the devices, and optionally features of the facility itself. FIG. 2 illustrates that the simulator may include a user interface 201 with an electronic display. The display may be controllable by a touch-screen operation, by an audio input with voice commands, by a keyboard or keypad, or by another user input device. The display may display a representation of the facility 204, along with a set of luminaires 205a . . . 205n superimposed on the facility at the actual locations of those devices in the facility. The system may superimpose the luminaires 205a . . . 205n onto facility 204 locations using any suitable process, such as by mapping coordinate data for from the luminaire data set for each luminaire onto a corresponding set of coordinates available for the facility. This data for each of the luminaires may be included in one or more files (such as a JSON file) that includes the luminaire make/model, coordinates (x-y physical location), default brightness and RGB color, digital address in the control system (such as an address on a streaming DMX over ACN bus, and other data. The system may match the facility coordinates to the luminaires' coordinates to identify and position the luminaires in their corresponding facility location on the display.

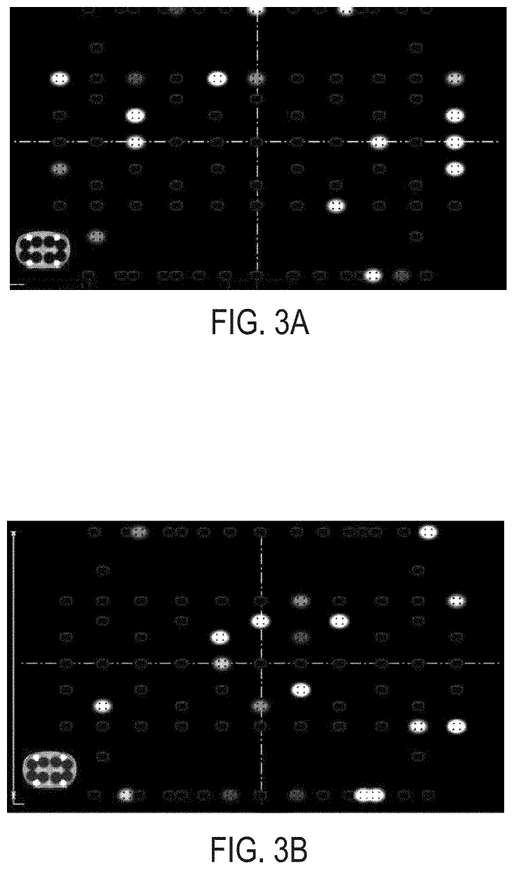

The simulator may be programmed to cause the appearance of the lighting devices shown on the display to simulate a scene on the display as it would appear in the real-world environment by “playing” the scenes' instructions and causing the luminaires shown on the display to change their appearance based on the settings that the scene uses to command the luminaires' operation over time during the scene. For a very simple example, FIG. 3A shows that at a first point in time in the scene a first group of lights will be on, while FIG. 3B shows that at a second point in time in the scene a different group of lights will be on. Additional visual representations of the scene may appear on the lights over time, such as different colors, brightnesses, beam spreads, etc. For example, in FIG. 3A some of the luminaries appear to relatively brighter than others, while in FIG. 3B a different group of luminaires appears to be lit, and the relative variations of brightness among the luminaires has also changed. In this way, the scene is animated on the display as it would appear in the real world.

In some embodiments, the scene data may be encoded according to a lighting control protocol such as that described in the American National Standards Institute (“ANSI”) “Entertainment Technology—USITT DMX512-A—Asynchronous Serial Digital Data Transmission Standard for Controlling Lighting Equipment and Accessories”, which is commonly referred to a DMX512 or simply DMX. This document will use the term “DMX” to refer to the DMX512 standard, and its various variations, revisions and replacements, including any future revisions or replacements that may be consistent with the processes described in this disclosure. In addition, other communication protocols such as I2C or Ethernet communication protocols may be used.

The system may receive the scene data from the data store according to the DMX protocol (or another protocol) as communication packets, and it may decode the packets to interpret the data used to operate the virtual representations of the luminaires. Optionally, the system may be programmed to recognize that a collection of streamed packets can be bundled together to form a data structure. A header in any packet may signal the start of a new data structure. Each data structure will include multiple “channels” (i.e., positions in the stream of bytes), and various lighting fixtures in the facility may be configured to subscribe to specific channels. Accordingly, the simulator may have the subscription information for actual lights in the facility, and it may use that subscription information to identify the channel to which each light subscribes, and then use the information within that channel to control that light's virtual representation in the simulator.

For example, a 512-byte data structure may include 51 channels containing 10 bytes each. Each fixture may subscribe to a channel by associating the fixture with the starting address of a channel (e.g., “start address 20” may signal a subscription for bytes 20-29 in the data structure). The simulator will examine the start address and each byte offset from the start address and use the information contained in those bytes to change the virtual representations of the lights associated with the start address. For example:

The start address (offset 0) may contain a brightness value for white LEDs in the luminaire.

Offset 1 may provide the color temperature to apply to white LEDs. A baseline color temperature (such as 4000K) may be mapped to byte values between 0 and 255.

Offset 2 may provide the beam angle for white LEDs.

Offset 3 may control the luminaire's red LEDs.

Offset 4 may control the luminaire's blue LEDs.

Offset 5 may control the luminaire's green LEDs.

Offset 6 may control the amber LEDs.

Other encoding and decoding schemas may be used. The system may then use this decoded information to change the appearance of the virtual representations on the display so that the virtual representations are consistent with the information contained in the luminaire's channel by causing the pixels in a field of illumination around each displayed luminaire to exhibit directional, brightness and/or color characteristics that correspond to the characteristics assigned to the luminaire in the scene data over various points in time.

The stream will continuously provide new data, and the simulator will update each luminaire's virtual representations each time new data arrives on that luminaire's channel.

When mapping the scene data to the environment, the system may determine a color value for the light emitted and a beam spread (i.e., light size) for the emitted light associated with each luminaire. The beam spread may be fixed, or it may vary with the brightness level of the light. The system may then apply a darkening filter to all pixels not within the beam spread of the light to determine a new pixel color value for each pixel as follows:

PixNew(R,G,B)=PixOld(R,G,B)*DarkFilter(R,G,B)

where PixNew is the new pixel color value, PixOld is the previous pixel color value, and DarkFilter is a value between 0 and 255, optionally as determined by an ambient light sensor.

Alternatively the system may substitute a LightFilter value for the DarkFilter value in the equation above, where the LightFilter value is a value associated with light within the luminaire's beam spread, and the function is applied to pixels that are within (instead of outside of) the beam spread. Either way, the effect will be that pixels outside of the luminaire's beam spread will appear to be darker than those within the beam spread when the luminaire is on during the scene, and the value of the pixels within the pixel will be determined by the color value, brightness or other characteristics of the light that is to be emitted by the luminaire at any given point in time.

Referring back to FIG. 2, the simulator may cause the display to output a user interface 210 via which the system may receive user inputs or commands to control one or more parameters of the simulation. For example, the user interface may include a scene selector interface 215, a run/stop scene command input 211, an interface to change one or more features of the facility environment 212 (such as daylight/nighttime settings—see FIG. 2 for an example daytime scene, and FIGS. 3A-3B for an example nighttime scene), and luminaire parameter settings such as brightness and/or color temperature 213. In addition, the user interface may include a scene definition interface (which may be included in the user interface 210 shown, or optionally a separate screen or a different configuration of the user interface 210) in which a user may define the light output settings and operational timing for each of a facility's luminaires in any particular scene. The system may then play the scene so that the display provides a visual representation of the scene to a user, and the user can input adjustments to any of the luminaire's parameters and replay the scene with the updated parameters to see the effect of the changes.

By causing the visual representations of the lights to appear on the screen as they would in a scene, the visual representation can help scene developers identify errors in scene definition parameters. For example, if a particular luminaire does not appear as expected in a scene (e.g., off when it should be on, on when it should be off, incorrect brightness or color, etc.), the user may command the system to display the scene parameters that control the light at that time so that the user can see those parameters and adjust them to fix the programming error.

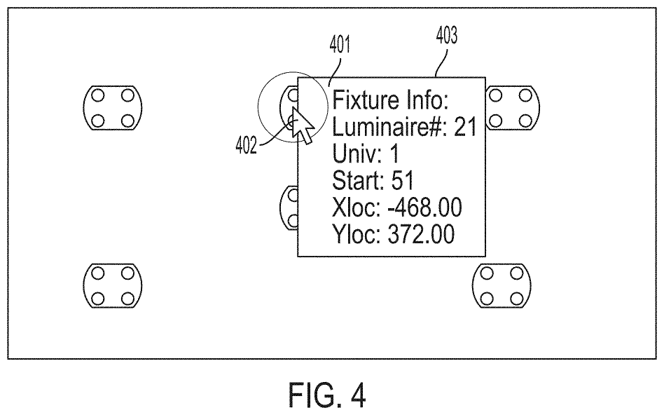

Referring to FIG. 4, the simulator may, in response to a user input such as touching a luminaire 401 on the touch screen or hovering over the luminaire 401 with a cursor 402, or receiving spoken audio with a fixture identifier, cause a pop-up box 403 or other display segment to appear with various characteristics of the luminaire, such as fixture ID, location (coordinates). Optionally the, simulator may extract, from the scene data for the selected scene, characteristics of light that the selected luminaire is emitting in the scene at the time that the user input is detected. If so, it may include in the box information about the luminaire settings and/or light output characteristics that the selected luminaire is emitting in the scene at the time that the user input is received (i.e., at the time in the scene at which the pop-up box appears).

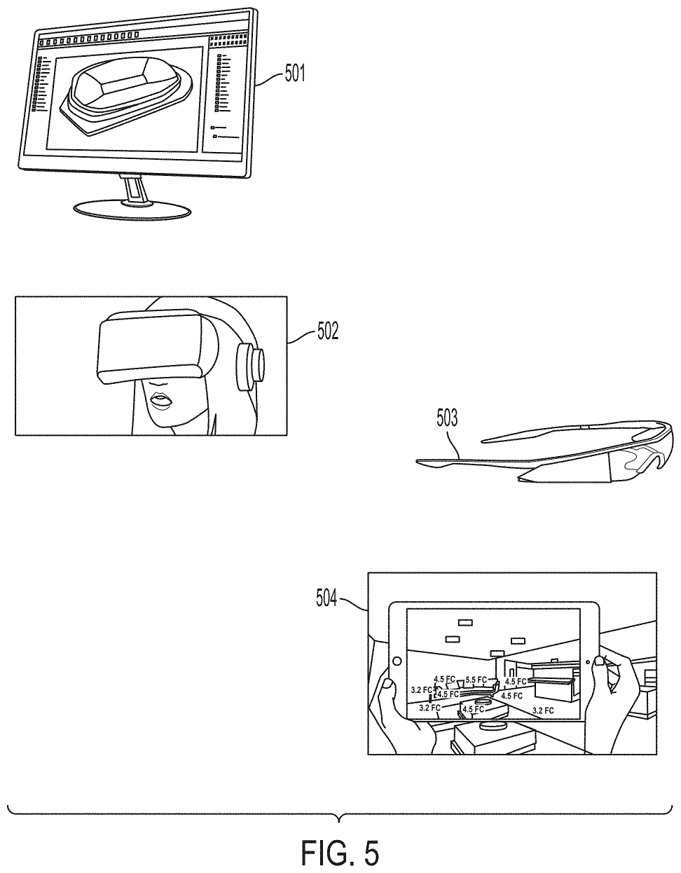

FIG. 5 illustrates that the two-dimensional representation shown in FIGS. 3 and 4 may be extended to a three-dimensional facility representation. This may be done on a 2D display 501 using software and programming techniques such as those used in computer-aided design. Or it may be presented via the display of awearable virtual reality (VR) display device 502 such as a headset. In either of these situations, the luminaire location data and facility data will include 3D coordinates so that the luminaires may be mapped onto the appropriate location of the facility at any position in 3D space. In addition, in some embodiments the device may use an augmented reality (AR) or mixed reality (MR) display device 503 such as a headset or gogglesin which the actual facility can be seen through a transparent (or partially transparent) display, or a device with a camera 504 that is configured to show an image of the actual facility on the display. The system may map the luminaires onto appropriate locations of the display using GPS coordinates of the display device as well as position and orientation data taken from sensors in the device such as accelerometers, gyroscopes and/or inertial measurement units. As with the 2D model described above, the luminaire data for the 3D model may be included in one or more files (such as a JSON file), but in this case the data will include 3D coordinates (x-y-z physical location), The system may then match the facility's 3D coordinates to the luminaires' 3D coordinates to identify and project the luminaires to their corresponding facility location on the display.

In a 3D situation, the display can not only show the luminaires' location, but also a 3D representation of the light output by the luminaires as the scene plays, so that the display shows how the luminaires' output will actually appear on the field. To do this, the system may include a 3D model for each light, which is a data set showing the characteristics of light output by the luminaire in three dimensions within the luminaire's field of illumination, with characteristics such as distance, shape, beam spread, brightness, color, ext. for each voxel in the path of the light output by the light. Since multiple lighting devices will be present in the facility, many voxels will be in the paths of multiple lighting devices, so the system will calculate and display, for each voxel, an overall lighting characteristic set for each voxel. At any given point in time in the scene, for any voxel that is within the field of illumination of a single luminaire, the brightness and color values applied to that voxel may correspond to those of the light emitted by the luminaire at that point in time, as obtained from the luminaire's 3D model. However, in practice most voxels may be within the field of illumination of multiple luminaires, in which case the system will calculate the brightness and color values applied to that voxel as a function (such as a sum, a weighted average, or another function) of the characteristics of the light emitted by all luminaires that are sources of light for that pixel (i.e., all luminaires whose fields of illumination include the voxel) at that point in time. The same process may be applied to pixels if a 2D representation is used instead of a 3D representation.

For example, the display device may generate or retrieve a display model, such as a polygon (e.g., a 2D polygon, a 3D polygon, a combination of 2D and/or 3D polygons, graphical images, etc.) or another type of image(s), for each luminaire's 3D model and combine the multiple display models to generate a display model representing a combined lighting pattern for multiple luminaires in a scene. For example, the system may combine polygons that have parameters corresponding to the photometric data of each luminaire's 3D model to generate a combined polygon that has display parameters that account for the display parameters of the individual polygons. The system may retrieve the individual polygons or other types of display models from a local storage or a remote source such as a remote server.

In some example embodiments, the system may account for lighting conditions in the target area in generating the display model representing the lighting pattern resulting from the luminaire's 3D model. For example, the system may use the lighting condition received from and sensed by an ambient light sensor as well as the photometric data of each luminaire's 3D model to generate the display parameters of a polygon that is displayed on the display overlaid on the real-time image of the target area. An AR/MR device may identify reflective surfaces, walls, furniture, etc. as described above and account for reflections, shadows, etc. in generating the polygon that is overlaid on the real-time image.

The luminaires'3D models may be displayed in the real-time image of a target area, enabling the user to assess how the corresponding luminaires or lighting effect will look when a scene is played. Because the luminaire's 3D models are associated with physical locations in the facility and because the lighting display models (e.g., the polygon(s)) are associated with the luminaires' models, a user may move about the facility while holding or wearing an AR/MR device and see the resulting lighting effect of a scene at different locations from different vantage points in the facility. As the user moves about the facility, the shape of the lighting pattern displayed on the display may change depending on the part of the facility viewable by the camera of the AR/MR device and the corresponding real-time image displayed on the display.

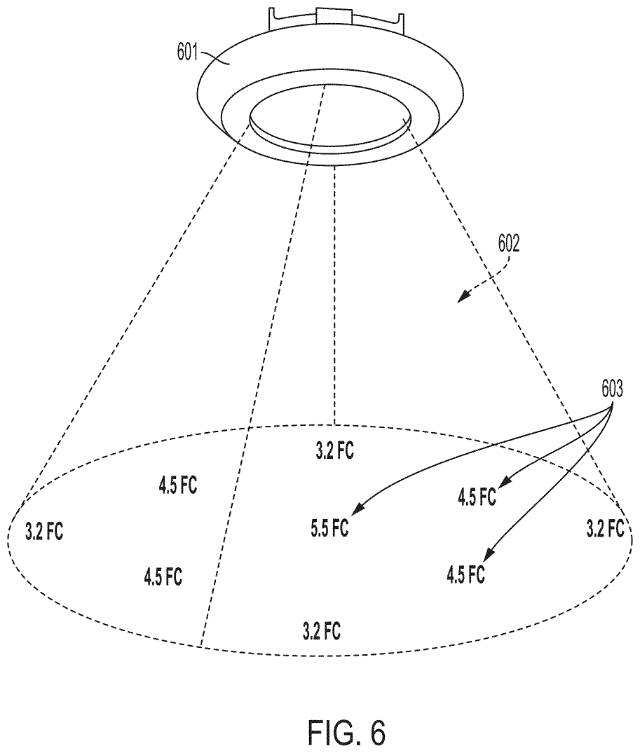

FIG. 6 illustrates an example 3D model of a luminaire 601 and pattern of light emitted by the luminaire 601. The emitted light pattern includes illuminance levels that are based on photometric data or another gradient of lighting data associated with the luminaire. The photometric data 602 associated with the luminaire 601 may be illustrated to convey lighting distribution shape, color temperature as well as the illuminance levels indicated by the illuminance level values 603, for example, at a surface that is a particular distance from the luminaire 601. Although the illuminance level values 603 are shown for a particular surface, the photometric data may include illuminance level values at different distances. The system may use the photometric data such as lighting distribution shape, color temperature, the illuminance levels, etc. to generate a display model that is overlaid on the real-time image of the facility displayed on the display device. Although this document uses a polygon as an example of a display model, other types of display models such as other shapes or images also may be used.

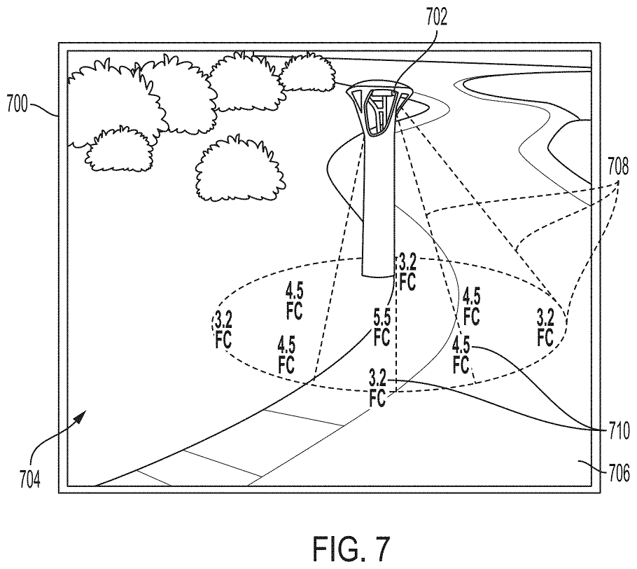

FIG. 7 illustrates a 3D model of a luminaire and a lighting pattern including illuminance values overlaid on a real-time image (which may be an actual view or a view captured by a camera) of a target physical area within the facility according to an example embodiment. A real-time image 704 of a target physical area as viewed by a camera of the simulator be output on the display 700. Using the simulator, a 3D model 702 of a luminaire may be displayed as shown in FIG. 7. The 3D model 702 is overlaid on the real-time image 704 of the target physical area on the display 700 in a similar manner as described above.

Optionally, the system will determine illuminance values 710 for voxels that are within the beam spread of the luminaire. To illustrate, the illuminance values 710 may indicate brightness levels of the light that can be provided by the lighting fixture represented by the 3D model 702. The illuminance values 710 may be in units of foot-candle (FC) and may be generated based on intensity values extracted from a photometric data file associated with the 3D model or with the luminaire represented by the 3D model. The photometric data file may be an Illuminating Engineering Society (IES) file or another photometric data file, in JSON or other format as described earlier. In some embodiments, lighting data may be input to the simulator by a user instead of or in addition to the photometric data. Dotted lines 708 illustrate boundaries of the beam spread and shape of the emitted light as viewed from one angle. For example, the lines 708 may be associated with a minimum threshold, where the shape (i.e., the outer contour) of the light is defined based on illuminance values that are above the minimum threshold (e.g., 3 FC). The minimum threshold may be set based on the expected effect of a light at various illuminance values or various distances from the luminaire.

As illustrated in FIG. 7, some areas of the ground 706 may be associated with higher brightness level (e.g., 5.5 foot-candle (FC)) while other areas may be associated with a relatively darker level (e.g., 3.2 FC). As a user moves in the target area holding the simulator's AR or MR device, the real-time image displayed on the viewport/display screen of the device (or the image seen through the display) is changed as different parts of the target physical area come into the field of view. Because the 3D model remains virtually anchored to a location (e.g., based on coordinates) in the facility, the 3D model of the luminaire can be viewed from different sides on the viewport/display screen as the device moves in the facility as long as the virtual location of the 3D model in the facility area is in the field of view of the device.

As the user moves around in the target physical area holding or wearing the AR/MR device, different illuminance values may be displayed on the display depending on the part of the facility that is displayed relative to the virtual locations of the 3D model and/or the illuminance values. The illuminance values are anchored to locations in the facility (e.g., locations on the ground 706), although different illuminance values may be displayed on the display depending on the particular real-time image that is in the field of view.

In some example embodiments, the illuminance values 710 for each pixel (or voxel) may be generated for various locations based on the height at which the light source of the lighting fixture as represented by the 3D model is located. The height of the light source of the lighting fixture may be incorporated in the 3D model of the lighting fixture. Horizontal angle, vertical angle, and intensity information provided in an IES file with respect to different lighting fixture installation heights may be used to generate illuminance values with respect to various locations on a horizontal surface and/or a vertical surface. The information in the IES file may also be used to determine color temperature and lighting shape of the light that can be provided by a lighting fixture. In this specification, the term “height” and the phrases “installation height” and “mounting height” used with respect to a lighting fixture are intended to refer to the location of the light source of the lighting fixture with respect to a floor or a similar surface below the lighting fixture or on which the lighting fixture is installed.

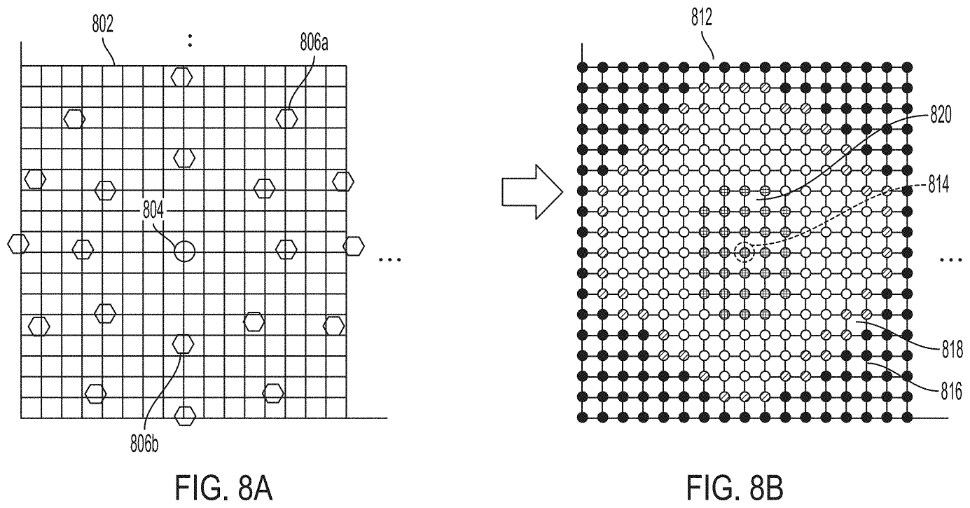

FIG. 8A illustrates a surface intensity matrix 802 in the form, of a two-dimensional array that is partially populated with light intensity data extracted from a photometric data file according. By way of example, the surface intensity matrix 802 may represent luminous intensity values on a surface such as a floor, and the expected mounting height of a lighting fixture may be used to extract the relevant intensity values from an IES file associated with the lighting fixture, which would be located at the center 804 of the surface intensity matrix. For example, the surface intensity matrix 802 may be considered as covering a floor or another surface that can be illuminated by a light from a lighting fixture installed at a mounting height above the floor or the other surface, positioned at the center 804 of the matrix at a mounting height above a floor level. Horizontal angle, vertical angle, and intensity values for the particular expected mounting height of the lighting fixture may be extracted from the IES file, and intensity values may be identified for each point (e.g., 806a, 806b) of the matrix, where the intensity values represent the intensity of light emitted by the luminaire at various locations on the floor. The populated locations of the surface intensity matrix 802 may correspond to particular horizontal and vertical angles included in the IES file with respect to the expected installation height of the lighting fixture above the floor at the location 804.

In some example embodiments, linear interpolations of the populated intensity values may be performed to fully or mostly populate the surface intensity matrix 802. The linear interpolations may be performed between two intensity values in a manner that can be readily understood by those of ordinary skill in the art with the benefit of this disclosure. The size and resolution of the surface intensity matrix 802 may depend on the type of lighting fixture. For example, the size and resolution of the surface intensity matrix that is used for a linear lighting fixture may be different from the size and resolution of the surface intensity matrix that is used with a round lighting fixture. Size and resolutions for various surface intensity matrices may be pre-defined for different lighting fixtures.

In some example embodiments, another level (e.g., a table surface) instead of a floor level may be used to determine the net height of a lighting fixture above the level in order to select the relevant intensity, horizontal angle, and vertical angle values from an IES file. Although particular locations of the surface intensity matrix 802 are shown as populated, in alternative embodiments, more or fewer locations or different locations may be populated with intensity values without departing from the scope of this disclosure.

In some example embodiments, after being fully or mostly populated, the surface intensity matrix 802 may be used to generate an illuminance matrix, which is a two-dimensional array populated with light illuminance data. To illustrate, FIG. 8B illustrates an illuminance matrix 812 populated with light illuminance data generated from light intensity data of the surface intensity matrix 802 of FIG. 8A according to an example embodiment. The illuminance values that are used to populate each point in the illuminance matrix 812 may be generated from the light intensity values of the surface intensity matrix 802 using Equation (1) below.

$${E}_{p} = \frac{d Φ}{{dA}_{p}} = \frac{I ( θ , Ψ ) d {ω}_{p}}{{dA}_{p}} = \frac{I ( θ , Ψ ) d {A}_{p} cos ( ξ )}{{dA}_{p} {D}^{2}} = \frac{I ( θ , Ψ ) cos ( ξ )}{{D}^{2}} \qquad Eq . 1$$

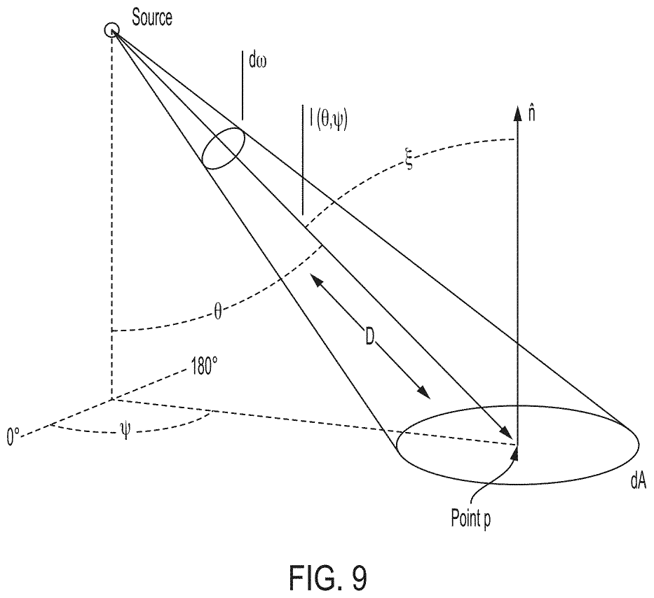

In Equation (1), and as illustrated in FIG. 9, Eₚ represents the illuminance value of a point in a plane, θ and ζ represent vertical angles (ζ=0 when the luminaire is directly above P and the luminaire's plane and the surface are therefore parallel, Ψ represents a horizontal angle, and dAₚ represents the illuminated area at point P.I(θ, Ψ) represents luminance intensity values for vertical and horizontal angles θ and Ψ for the particular expected mounting height h of the lighting fixture.

Using different shades (or colors) for illustrative purposes, where each shade (or color) represents an illuminance value, FIG. 8B shows the illuminance values (e.g., illuminance values 816, 818, 820) can vary depending on the relative distances of the different locations of the illuminance matrix 812 from the location 814 of the lighting fixture. The location 814 of the lighting fixture is considered as being directly above the floor level at a center of the matrix, where the floor level is represented by the illuminance matrix 812.

In some example embodiments, illuminance values that are below a threshold value may be dropped from the illuminance matrix 812. For example, the illuminance values represented by the darkest shade (black) 816 in FIG. 8B may be dropped from the illuminance matrix 812 in subsequent operations performed on the illuminance matrix 812.

Although particular locations are shown as populated with particular shades or colors in the illuminance matrix 812, in alternative embodiments, the locations may be populated with different shades or colors without departing from the scope of this disclosure. The simulator may execute software code to perform the operations described above with respect to FIGS. 8A and 8B, for example, in response to relevant user inputs.

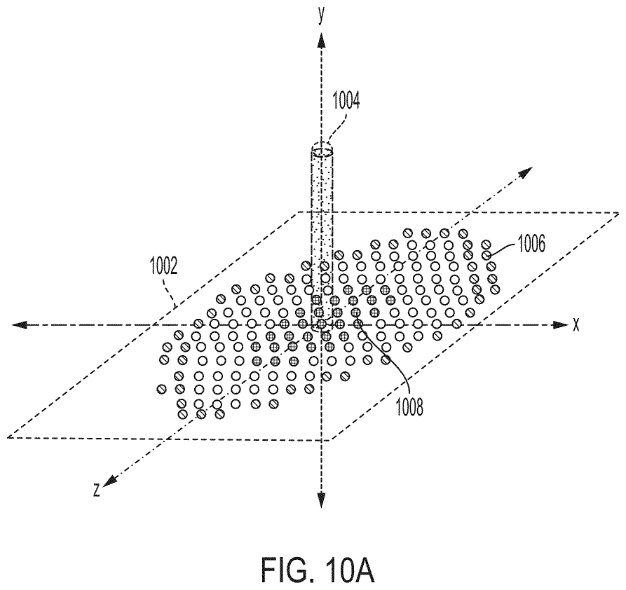

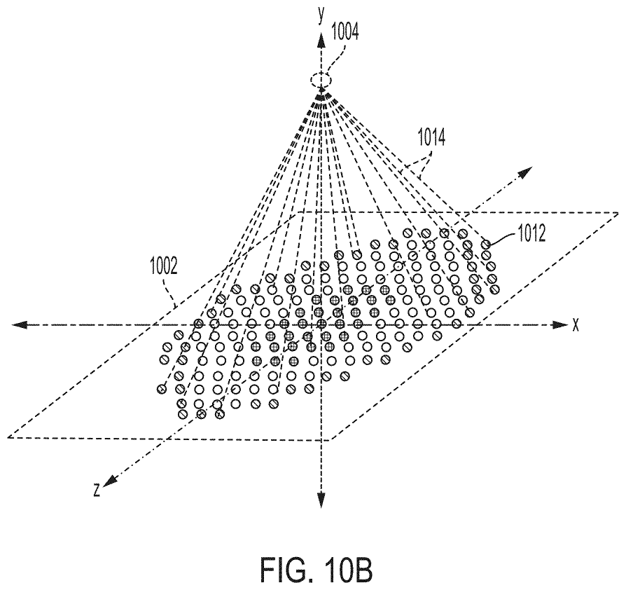

In some example embodiments, the illuminance information of the illuminance matrix 812 may be mapped or otherwise changed to augmented reality display information, before or after some illuminance values that are below a threshold value are dropped. FIG. 10A illustrates augmented reality display information mapped from the light illuminance data of the illuminance matrix 812 of FIG. 8B according to an example embodiment. FIG. 10B illustrates the augmented reality display information of FIG. 10A with a lighting shape according to an example embodiment. In FIG. 10A, a location 1004 of a lighting fixture is shown above a center of the floor level area 1002 at an expected installation or mounting height. The location 1004 of the lighting fixture corresponds to the location 804 shown in FIG. 8A and the location 814 shown in FIG. 8B and represents the location of the lighting fixture at an expected installation/mounting height above the floor level area 1002, which corresponds to the illuminance matrix 812. In some example embodiments, the reference to augmented reality in this specification is intended to include mixed reality (MR) as can be understood by those of ordinary skill in the art with the benefit of this disclosure.

Using different shades (or colors) for illustrative purposes, where each shade (or color) represents an illuminance value, FIG. 10A shows the illuminance values (e.g., illuminance values 1006, 1008) can vary depending on the relative distances of the locations on the floor level area 1002 from the location 1004 of the lighting fixture above the center of the floor level area 1002. As can be seen in FIG. 10A, illuminance values for locations that are relatively too distant from the location 1004 of the lighting fixture have been removed, for example, based on comparisons of the illuminance values against a minimum threshold (e.g., 2.5 FC). To illustrate, the floor level area 1002 would be more fully populated if the relatively low illuminance values are not removed. The illuminance values for such locations may be dropped or removed by performing the comparison against the minimum threshold before or after transforming the illuminance information in the two-dimensional array 812 of FIG. 8B to the augmented reality display information displayed in FIG. 10A.

FIG. 10B shows that in some example embodiments, lines, such as the dotted lines 1014, extending between the location 1004 of the light and the populated locations in each planar matrix (e.g., the shaded circle 1012) at or above the floor level of the facility may represent a general lighting shape of the light that would be provided by the lighting fixture installed at the location 1004. For example, the dotted lines 1014 may extend between the location 1004 and the points (e.g., the shaded circle 1012) that represent outer contour of the light as determined by comparing the illuminance values represented by the shaded circles against the minimum threshold of illuminance.

In some alternative embodiments, the augmented reality matrix may include multiple planes such as the floor level area 1002 plane, but at various heights above the floor, to include illuminance values at various points in space between the luminaire's location and the floor. Thus, luminance values will be assigned to each voxel in each plane, where each voxel has a x, y, z coordinate values.

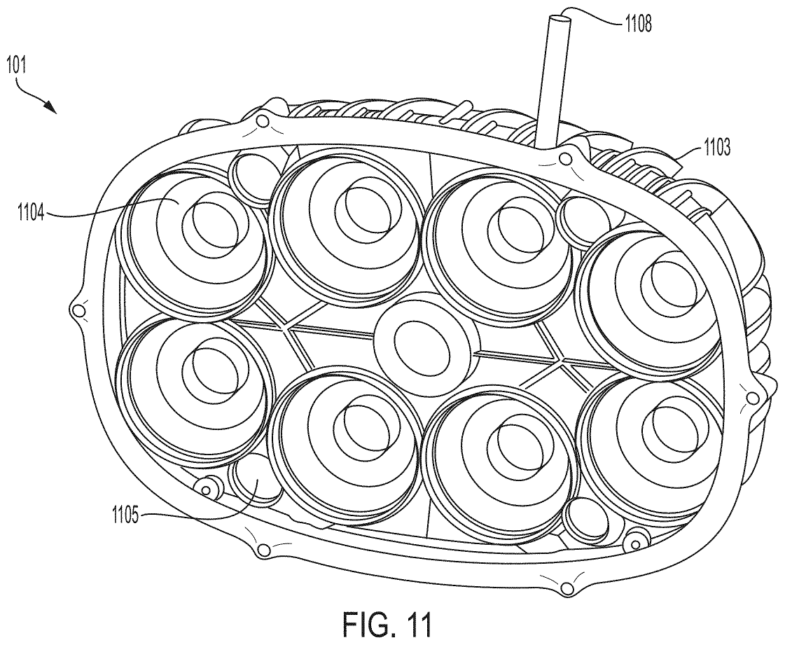

Referring to FIG. 11, an example lighting device 101 for which this system may provide a simulation will include an optical radiation source, such as any number of lighting modules that include LEDs, and in various embodiments a number of LED modules sufficient to provide a high intensity LED device. In various embodiments, a lighting device may include multiple types of LED modules. For example, a lighting device may include a first type of LED module 1104 having LEDs that are configured to selectably emit white light of various color temperatures, along with a second type of LED module 1105 having LEDs that are configured to selectably emit light of various colors. The lighting device 101 may include a housing 1103 that holds electrical components such as a fixture controller, a power source, and wiring and circuitry to supply power and/or control signals to the LED modules. It may also include communication components 1108 such as a transceiver, antenna and the like.

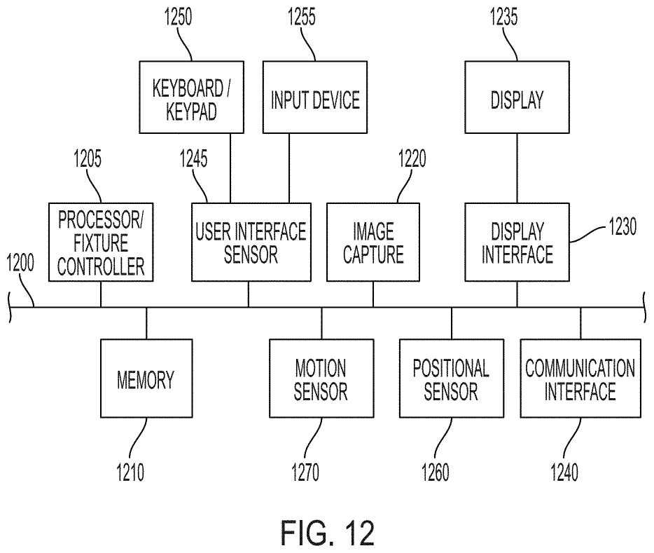

FIG. 12 is a block diagram of hardware that may be included in any of the electronic devices described above, such as a simulator, or an element of the lighting control system. A bus 1200 serves as an information highway interconnecting the other illustrated components of the hardware. The bus may be a physical connection between elements of the system, or a wired or wireless communication system via which various elements of the system share data. Processor 1205 is a processing device of the system performing calculations and logic operations required to execute a program. Processor 1205, alone or in conjunction with one or more of the other elements disclosed in FIG. 12, is an example of a processing device, computing device or processor as such terms are used within this disclosure. The processing device may be a physical processing device, a virtual device contained within another processing device, or a container included within a processing device. If the electronic device is a lighting device, processor 1205 may be a component of a fixture controller if the electronic device is a lighting device, and the device would also include a power supply and optical radiation source as discussed above.

A memory device 1210 is a hardware element or segment of a hardware element on which programming instructions, data, or both may be stored. An optional display interface 1230 may permit information to be displayed on the display 1235 in audio, visual, graphic or alphanumeric format. Communication with external devices, such as a printing device, may occur using various communication interfaces 1240, such as a communication port, antenna, or near-field or short-range transceiver. A communication interface 1240 may be communicatively connected to a communication network, such as the Internet or an intranet.

The hardware may also include a user input interface 1245 which allows for receipt of data from input devices such as a keyboard or keypad 1250, or other input device 1255 such as a mouse, a touchpad, a touch screen, a remote control, a pointing device, a video input device and/or a microphone. Data also may be received from an image capturing device 1220 such as a digital camera or video camera. A positional sensor 1260 and/or motion sensor 1270 may be included to detect position and movement of the device. Examples of motion sensors 1270 include gyroscopes or accelerometers. Examples of positional sensors 1260 such as a global positioning system (GPS) sensor device that receives positional data from an external GPS network. The motion and positional sensors may be used by the simulator to determine the device's orientation and position in a facility, and relate that data to the coordinates that will be visible in the electronic device's field of view.

The features and functions described above, as well as alternatives, may be combined into many other different systems or applications. Various alternatives, modifications, variations or improvements may be made by those skilled in the art, each of which is also intended to be encompassed by the disclosed embodiments.

Terminology that is relevant to this disclosure includes:

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” (or “comprises”) means “including (or includes), but not limited to.”

In this document, when terms such as “first” and “second” are used to modify a noun, such use is simply intended to distinguish one item from another, and is not intended to require a sequential order unless specifically stated. The term “approximately,” when used in connection with a numeric value, is intended to include values that are close to, but not exactly, the number. For example, in some embodiments, the term “approximately” may include values that are within ±10 percent of the value.

In this document, the terms “lighting device,” “light fixture,” “luminaire” and “illumination device” are used interchangeably to refer to a device that includes a source of optical radiation. Sources of optical radiation may include, for example, light emitting diodes (LEDs), light bulbs, ultraviolet light or infrared sources, or other sources of optical radiation. In the embodiments disclosed in this document, the optical radiation emitted by the lighting devices includes visible light. A lighting device will also include a housing, one or more electrical components for conveying power from a power supply to the device's optical radiation source, and optionally control circuitry.

In this document, the terms “controller” and “controller device” mean an electronic device or system of devices containing a processor and configured to command or otherwise manage the operation of one or more other devices. For example, a “fixture controller” is intended to refer to a controller configured to manage the operation of one or more light fixtures to which the fixture controller is communicatively linked. A “gateway controller” refers to a central server or other controller device that is programmed to generate commands, or is in communication with a server or other electronic device from which it receives commands from a remote electronic device, and the gateway controller routes the commands to appropriate lighting device fixture controllers in a network of lighting devices. This document may use the term “lighting device controller” to refer to a component when the component may be either a gateway controller or a fixture controller. A controller will typically include a processing device, and it will also include or have access to a memory device that contains programming instructions configured to cause the controller's processor to manage operation of the connected device or devices.

The terms “electronic device” and “computing device” refer to a device having a processor, a memory device, and a communication interface for communicating with proximate and/or local devices. The memory will contain or receive programming instructions that, when executed by the processor, will cause the electronic device to perform one or more operations according to the programming instructions. Examples of electronic devices include personal computers, servers, mainframes, virtual machines, containers, gaming systems, televisions, and portable electronic devices such as smartphones, wearable virtual reality devices, Internet-connected wearables such as smart watches and smart eyewear, personal digital assistants, tablet computers, laptop computers, media players and the like. Electronic devices also may include appliances and other devices that can communicate in an Internet-of-things arrangement, such as smart thermostats, home controller devices, voice-activated digital home assistants, connected light bulbs and other devices. In a client-server arrangement, the client device and the server are electronic devices, in which the server contains instructions and/or data that the client device accesses via one or more communications links in one or more communications networks. In a virtual machine arrangement, a server may be an electronic device, and each virtual machine or container also may be considered to be an electronic device. In the discussion below, a client device, server device, virtual machine or container may be referred to simply as a “device” for brevity. Additional elements that may be included in electronic devices have been discussed above in the context of FIG. 12.

In this document, the terms “memory” and “memory device” each refer to a non-transitory device on which computer-readable data, programming instructions or both are stored. Except where specifically stated otherwise, the terms “memory” and “memory device” are intended to include single-device embodiments, embodiments in which multiple memory devices together or collectively store a set of data or instructions, as well as one or more individual sectors within such devices.

In this document, the terms “processor” and “processing device” refer to a hardware component of an electronic device (such as a controller) that is configured to execute programming instructions. Except where specifically stated otherwise, the singular term “processor” or “processing device” is intended to include both single processing device embodiments and embodiments in which multiple processing devices together or collectively perform a process.

A “controller device” is an electronic device that is configured to execute commands to control one or more other devices or device components, such as driving means of illumination device, illumination devices, etc. A “controller card” or “control card” or “control module” or “control circuitry” refers to a circuit component that acts as the interface between an input interface (such as an input interface of a controller device) and a lighting device.

1. A lighting device simulation system, comprising:
a data store containing location data for a plurality of luminaires that are located in a facility, along with one or more characteristics of light that each of the luminaires is capable of emitting;
a data store containing structural feature data for the facility, along with location data for the structural features;
a data store containing scene data for a plurality of scenes that may be used to control operation of the luminaires;
a processor;
a display; and
programming instructions that are configured to cause the processor to, in response to receiving a selection of one of the scenes, play the selected scene by:
mapping location data for structural features of the facility to points on the display,
mapping location data for a group of the luminaires of the facility to a subset of the points on the display,
causing the display to output virtual representations of luminaires in the group at each point in the subset of points, and, while outputting each virtual representation of a luminaire:
for each of a plurality of time elements in the scene:
identifying one or more light output characteristics for the luminaire, and
causing the virtual representation to output a visual indicator that corresponds to the light output characteristics so that the visual indicators for at least some of the virtual representations are varied over time.

2. The system of claim 1, further comprising additional programming instructions that are configured to cause the processor to:
cause the display to output the structural features of the facility at the points on the display; and
when causing the display to output the virtual representations of luminaires, superimpose the virtual representations of luminaires over a portion of the structural features as presented on the display.

3. The system of claim 1, wherein:
the display comprises an augmented reality display or mixed reality display; and
the programming instructions that are configured to cause the processor to cause the display to output the virtual representations of luminaires comprise instructions to superimpose the virtual representations of luminaires over a portion of the structural features of the facility as seen through the display.

4. The system of claim 1, wherein:
the system further comprises a camera; and
the programming instructions that are configured to cause the processor to cause the display to output the virtual representations of luminaires comprise instructions to superimpose the virtual representations of luminaires over a portion of the structural features of the actual facility as seen in images captured by the camera and presented on the display.

5. The system of claim 1, wherein the programming instructions that are configured to cause the processor to play the selected scene comprise instructions to:
receive the scene data as a stream of data packets, wherein the data packets comprise a plurality of channels of data;
upon receipt of each channel of data:
identify a luminaire in the facility that subscribes to that channel,
extract the one or more light output characteristics from that channel, and
use the extracted light output characteristics to apply color or brightness values to one or more pixels or voxels of the display that are associated with the virtual representation of the identified luminaire.

6. The system of claim 1, wherein the programming instructions that are configured to cause the processor to output a visual indicator that corresponds to the light output characteristics for each luminaire comprise instructions to:
determine a color value for the luminaire and a beam spread for emitted light that is associated with the luminaire; and
perform one or more of the following when the luminaire is on in the selected scene:
apply a darkening filter to pixels that are not within the beam spread of the emitted light associated with the luminaire, or
apply a light filter to pixels that are within the beam spread of the emitted light associated with the luminaire.

7. The system of claim 1, further comprising additional programming instructions that are configured to cause the processor to:
receive, via the user interface, a modification to one or more light output characteristics for the luminaire;
save the modification to a memory as a modified scene; and
present the modification on the display by playing the modified scene.

8. The system of claim 1, further comprising additional programming instructions that are configured to cause the processor to:
detect a user input that selects a luminaire that is being output on the screen; and
in response to the user input, present on the display a pop-up box that shows characteristics of the selected luminaire or settings of the luminaire.

9. The system of claim 8, wherein the programming instructions that are configured to cause the processor to present on the display the pop-up box comprise instructions to:
extract, from the scene data for the selected scene, characteristics of light that the selected luminaire is emitting in the scene at the time that the user input is received; and
include in the box information about the characteristics of light that the selected luminaire is emitting in the scene at the time that the user input is received.

10. The system of claim 1, wherein the programming instructions that are configured to cause the processor to play the selected scene comprise instructions to:
for each of the luminaires in the group, retrieve a display model;
combine a plurality of the display models to generate an overall display model representing a combined lighting pattern for a plurality of the luminaires in the group; and
when causing the display to output virtual representations of the luminaires in the group, also causing the display to output a visual representation of the combined lighting pattern in the facility.

11. The system of claim 10, wherein the programming instructions that are configured to cause the processor to play the selected scene also comprise instructions to:
receive, from an ambient light sensor, an actual lighting condition for the facility at a location in the facility;
when generating the overall display model representing the combined lighting pattern, also factoring characteristics of the actual lighting condition into the combined lighting pattern.

12. The system of claim 10, wherein the programming instructions that are configured to cause the processor to play the selected scene also comprise instructions to display illuminance values of one or more pixels or voxels at corresponding locations within the visual representation of the combined lighting pattern.

13. A computer program product for providing a lighting device simulation system, the computer program product comprising one or more memory devices containing programming instructions that are configured to cause a processor to:
access a data store containing location data for a plurality of luminaires that are located in a facility, along with one or more characteristics of light that each of the luminaires is capable of emitting;
access a data store containing structural feature data for the facility, along with location data for the structural features;
access a data store containing scene data for a plurality of scenes that may be used to control operation of the luminaires; and
in response to receiving a selection of one of the scenes, play the selected scene on a display by:
mapping location data for structural features of the facility to points on the display,
mapping location data for a group of the luminaires of the facility to a subset of the points on the display,
causing the display to output virtual representations of luminaires in the group at each point in the subset of points, and, while outputting each virtual representation of a luminaire:
for each of a plurality of time elements in the scene:
identifying one or more light output characteristics for the luminaire, and
causing the virtual representation to output a visual indicator that corresponds to the light output characteristics so that the visual indicators for at least some of the virtual representations are varied over time.

14. The computer program product of claim 13, further comprising additional programming instructions that are configured to cause the processor to:
cause the display to output the structural features of the facility at the points on the display; and
when causing the display to output the virtual representations of luminaires, superimpose the virtual representations of luminaires over a portion of the structural features as presented on the display.

15. The computer program product of claim 13, wherein the programming instructions that are configured to cause the processor to cause the display to output the virtual representations of luminaires comprise instructions to, if the display comprises an augmented reality display or mixed reality display, superimpose the virtual representations of luminaires over a portion of the structural features of the facility as seen through the display.

16. The computer program product of claim 13, wherein the programming instructions that are configured to cause the processor to cause the display to output the virtual representations of luminaires comprise instructions to superimpose the virtual representations of luminaires over a portion of the structural features of the actual facility as seen in images captured by a camera and presented on the display.

17. The computer program product of claim 13, wherein the programming instructions that are configured to cause the processor to play the selected scene comprise instructions to:
receive the scene data as a stream of data packets that comprise a plurality of channels of data;
upon receipt of each channel of data:
identify a luminaire in the facility that subscribes to that channel,
extract the one or more light output characteristics from that channel, and
use the extracted light output characteristics to apply color or brightness values to one or more pixels or voxels of the display that are associated with the virtual representation of the identified luminaire.

18. The computer program product of claim 13, wherein the programming instructions that are configured to cause the processor to output a visual indicator that corresponds to the light output characteristics for each luminaire comprise instructions to:
determine a color value for the luminaire and a beam spread for emitted light that is associated with the luminaire; and
perform one or more of the following when the luminaire is on in the selected scene:
apply a darkening filter to pixels that are not within the beam spread of the emitted light associated with the luminaire, or
apply a light filter to pixels that are within the beam spread of the emitted light associated with the luminaire.

19. The computer program product of claim 13, further comprising additional programming instructions that are configured to cause the processor to:
receive, via the user interface, a modification to one or more light output characteristics for the luminaire;
save the modification to a memory as a modified scene; and
present the modification on the display by playing the modified scene.

20. The computer program product of claim 13, further comprising additional programming instructions that are configured to cause the processor to:
detect a user input that selects a luminaire that is being output on the screen; and
in response to the user input, present on the display a pop-up box that shows characteristics of the selected luminaire or settings of the luminaire.

21. The computer program product of claim 20, wherein the programming instructions that are configured to cause the processor to present on the display the pop-up box comprise instructions to:
extract, from the scene data for the selected scene, characteristics of light that the selected luminaire is emitting in the scene at the time that the user input is received; and
include in the box information about the characteristics of light that the selected luminaire is emitting in the scene at the time that the user input is received.

22. The computer program product of claim 13, wherein the programming instructions that are configured to cause the processor to play the selected scene comprise instructions to:
for each of the luminaires in the group, retrieve a display model;
combine a plurality of the display models to generate an overall display model representing a combined lighting pattern for a plurality of the luminaires in the group; and
when causing the display to output virtual representations of the luminaires in the group, also causing the display to output a visual representation of the combined lighting pattern in the facility.

23. The computer program product of claim 22, wherein the programming instructions that are configured to cause the processor to play the selected scene also comprise instructions to:
receive, from an ambient light sensor, an actual lighting condition for the facility at a location in the facility;
when generating the overall display model representing the combined lighting pattern, also factoring characteristics of the actual lighting condition into the combined lighting pattern.

24. The computer program product of claim 22, wherein the programming instructions that are configured to cause the processor to play the selected scene also comprise instructions to display illuminance values of one or more pixels or voxels at corresponding locations within the visual representation of the combined lighting pattern.
